(19) United States
(12) Patent Application Publication
(10) Pub. No.: US 2026/0181895 A1
(43) Pub. Date: Jun. 25, 2026

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventors: Yuta SAITO, Yokkaichi Mie (JP); Shinji MORI, Nagoya Aichi (JP)

(21) Appl. No.: 19/315,256

(22) Filed: Aug. 29, 2025

(30) Foreign Application Priority Data
Dec. 20, 2024 (JP) 2024-225010

(51) Int. Cl. H10B 43/27; H01L 23/00; H01L 25/065; H01L 25/18; H10B 41/10; H10B 41/27; H10B 41/35; H10B 43/10; H10B 43/35; H10B 80/00

(52) U.S. Cl. CPC H10B 43/27; H10B 41/10; H10B 41/27; H10B 41/35; H10B 43/10; H10B 43/35; H10B 80/00; H10W 90/00; H10W 90/792

(57) ABSTRACT

A semiconductor memory device includes: a stacked body including conductive and insulating layers that are alternately stacked in a first direction; memory pillars extending in the first direction in the stacked body; and a structure body segmenting the memory pillars and extending in the first direction in the stacked body. The structure body includes a crystalline conductor extending in the first direction in the stacked body, a first insulating film between the stacked body and the crystalline conductor, a crystalline semiconductor film between the crystalline conductor and the first insulating film, and a second insulating film between the crystalline semiconductor film and a side surface of the crystalline conductor. The crystalline conductor includes a first crystal region in contact with the crystalline semiconductor film and containing germanium, and a second crystal region on the first crystal region and in contact with the second insulating film in a second direction.

### CROSS-REFERENCE TO RELATED APPLICATION(S)

This application is based upon and claims the benefit of priority from Japanese Patent Application No. 2024-225010, filed Dec. 20, 2024, the entire contents of which are incorporated herein by reference.

### FIELD

Embodiments described herein relate generally to a semiconductor memory device and a method of manufacturing the semiconductor memory device.

### BACKGROUND

Semiconductor memory devices such as NAND flash memories in which memory cells are three-dimensionally arranged on semiconductor wafers are known.

### BRIEF DESCRIPTION OF THE DRAWINGS

FIG. 1 is a block diagram illustrating a configuration example of a memory.

FIG. 2 is a circuit diagram illustrating a circuit configuration of a memory cell array.

FIG. 3 is a schematic cross-sectional view illustrating an example structure of a semiconductor memory device.

FIG. 4 is an enlarged schematic view illustrating a part of a cross-section of the semiconductor memory device.

FIG. 5 is a schematic plan view illustrating a planar layout example of a memory pillar and a structure body.

FIG. 6 is a schematic cross-sectional view illustrating an example structure of the memory pillar.

FIG. 7 is a schematic cross-sectional view illustrating an example structure of the structure body.

FIGS. 8-13 are each a diagram illustrating an example of a cross-sectional structure while manufacturing the semiconductor memory device.

FIG. 14 is a schematic cross-sectional view illustrating an example structure of a structure body of the related art.

FIG. 15 is a schematic cross-sectional view illustrating an example structure of the structure body in the semiconductor memory device according to the embodiment.

FIG. 16 is a schematic cross-sectional view illustrating a first modification of the structure body.

FIG. 17 is a schematic cross-sectional view illustrating a second modification of the structure body.

FIG. 18 is a schematic cross-sectional view illustrating an example structure of the structure body of the related art.

FIG. 19 is a schematic cross-sectional view illustrating a third modification of the structure body.

### DETAILED DESCRIPTION

Embodiments provide a semiconductor memory device having high reliability.

In general, according to one embodiment, a semiconductor memory device includes: a stacked body including a plurality of conductive layers and a plurality of insulating layers and in which the conductive layers and the insulating layers are alternately stacked in a first direction; a plurality of memory pillars extending in the first direction in the stacked body; and a structure body segmenting the plurality of memory pillars and extending in the first direction in the stacked body. The structure body includes a crystalline conductor extending in the first direction in the stacked body, a first insulating film provided between the stacked body and the crystalline conductor, a crystalline semiconductor film provided between the crystalline conductor and the first insulating film and containing silicon, and a second insulating film provided between the crystalline semiconductor film and a side surface of the crystalline conductor and containing silicon and oxygen. The crystalline conductor includes a first crystal region coming into contact with the crystalline semiconductor film and containing germanium, and a second crystal region provided on the first crystal region and coming into contact with the second insulating film in a second direction perpendicular to the first direction.

Hereinafter, embodiments will be described with reference to the drawings. Relationships between thicknesses and planar dimensions of components described in the drawings, ratios of thicknesses of components, and the like differ from the actual product. In the embodiments, substantially the same components are given the same reference numerals, and descriptions thereof will be omitted as appropriate.

In the present specification, “connection” includes not only physical connection but also electrical connection unless specifically designated.

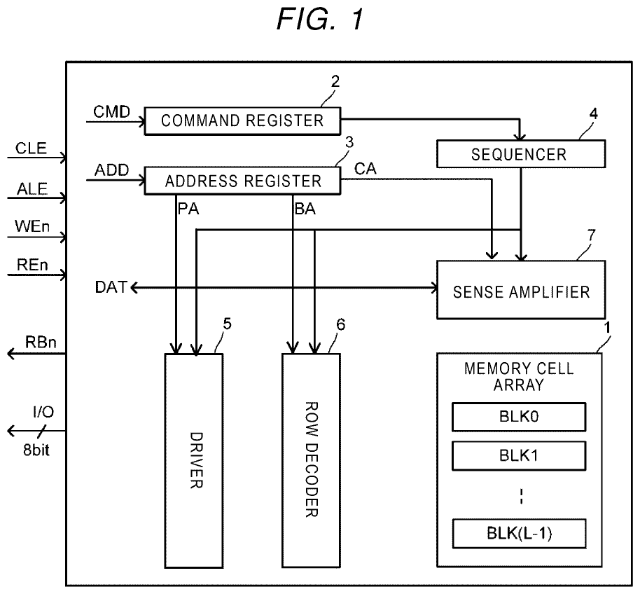

A configuration example of a semiconductor memory device will be described. FIG. 1 is a block diagram illustrating a configuration example of a memory. The memory includes a memory cell array 1, a command register 2, an address register 3, a sequencer 4, a driver 5, a row decoder 6, and a sense amplifier 7.

The memory cell array 1 includes a plurality of blocks BLK (BLK0 to BLK(L−1) (where L is a natural number of 2 or more). The block BLK is a collection of a plurality of memory cells that store data.

The command register 2 stores a command signal CMD received from a memory controller. The command signal CMD includes, for example, command data that causes the sequencer 4 to execute a read operation, a write operation, and an erase operation.

The address register 3 stores an address signal ADD received from the memory controller. The address signal ADD includes, for example, a block address BA, a page address PA, and a column address CA. For example, the block address BA, the page address PA, and the column address CA are each used to select a block BLK, a word line WL, and a bit line BL.

The sequencer 4 controls an operation of the memory. The sequencer 4 controls the driver 5, the row decoder 6, and the sense amplifier 7, and the like based on the command signal CMD stored in the command register 2 and executes operations such as the read operation, the write operation, and the erase operation.

The driver 5 generates voltages used for the read operation, the write operation, the erase operation, and the like. The driver 5 includes, for example, a DA converter. For example, the driver 5 applies a generated voltage to a signal line corresponding to the selected word line WL based on the page address PA stored in the address register 3.

The row decoder 6 selects one block BLK in the corresponding memory cell array 1 based on the block address BA stored in the address register 3. For example, the row decoder 6 transmits the voltage applied to the signal line corresponding to the selected word line WL to the selected word line WL in the selected block BLK.

In the write operation, the sense amplifier 7 applies a desired voltage to each bit line BL according to write data DAT received from the memory controller. In the read operation, the sense amplifier 7 determines data stored in a memory cell based on a voltage of the bit line BL and transmits a determination result as read data DAT to the memory controller.

Communication between the memory and the memory controller conforms to, for example, a NAND interface standard. For example, in the communication between the memory and the memory controller, a command latch enable signal CLE, an address latch enable signal ALE, a write enable signal WEn, a read enable signal REn, a ready/busy signal RBn, and an input/output signal I/O are used.

The command latch enable signal CLE indicates that the input/output signal I/O received by the memory is the command signal CMD. The address latch enable signal ALE indicates that the received signal I/O is the address signal ADD. The write enable signal WEn is a signal that instructs the memory to take in the input/output signal I/O. The read enable signal REn is a signal that instructs the memory to output the input/output signal I/O.

The ready/busy signal RBn is a signal that notifies the memory controller whether the memory is in a ready state in which a command from the memory controller can be received or a busy state in which the command cannot be received.

The input/output signal I/O is, for example, a signal of 8-bit width and may include signals such as the command signal CMD, the address signal ADD, and the write data DAT.

The memory and the memory controller described above may be combined to form one semiconductor memory device. Examples of such a semiconductor memory device include a memory card such as an SD card and a solid state drive (SSD).

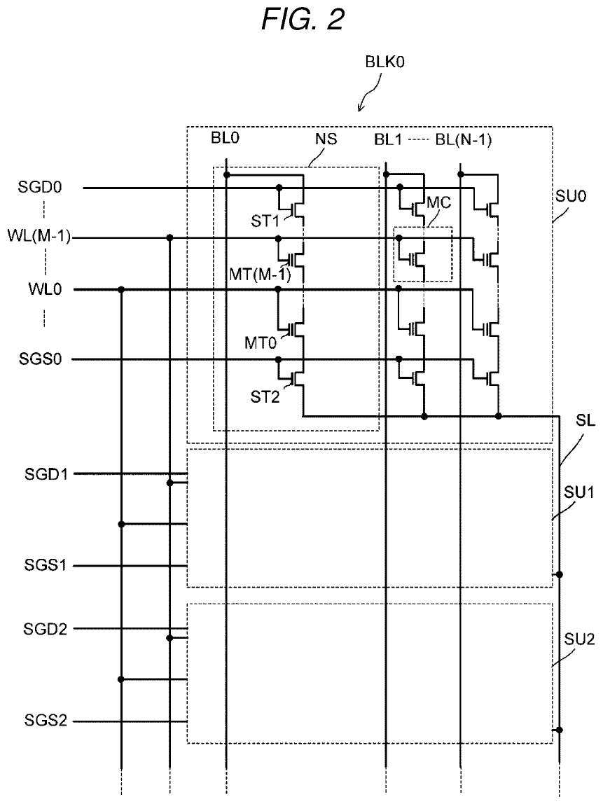

Next, a circuit configuration example of the memory cell array 1 will be described. FIG. 2 is a circuit diagram illustrating a circuit configuration of the memory cell array 1. In FIG. 2, the block BLK0 is illustrated as an example, and the same applies to the other blocks BLK.

The block BLK includes a plurality of string units SU. Each string unit SU includes a plurality of NAND strings NS. In FIG. 2, three string units SU (SU0 to SU2) are illustrated, but the number of string units SU is not limited to any particular number.

Each NAND string NS is connected to one of a plurality of bit lines BL (BL0 to BL(N−1) (where N is a natural number of 2 or more). Each NAND string NS includes, for example, a memory transistor MT, a select transistor ST1, and a select transistor ST2. The memory transistor MT makes up one memory cell MC. Each NAND string NS includes a plurality of memory cells connected in series.

The memory transistor MT includes a control gate and a charge storge layer, and can store data in a nonvolatile manner. The memory transistor MT may be a MONOS memory transistor in which an insulating layer is used as the charge storage layer, or may be an FG memory transistor in which a conductive layer is used as the charge storage layer. Hereinafter, in the embodiment, the MONOS memory transistor will be described as an example.

The control gate of the memory transistor MT is connected to the corresponding word line WL. One of a source and a drain of one of the plurality of memory transistors MT is connected to the other of a source and a drain of another memory transistor of the plurality of memory transistors MT. In FIG. 2, the plurality of memory transistors MT (MT0 to MT(M−1) (where M is a natural number of 2 or more) are illustrated, but the number of memory transistors MT is not limited to any particular number.

The select transistor ST1 is used to select the string unit SU during various operations. The number of select transistors ST1 is not limited to any particular number.

The select transistor ST2 is used to select the string unit SU during various operations. The number of select transistors ST2 is not limited to any particular number.

In each NAND string NS, a drain of the select transistor ST1 is connected to the corresponding bit line BL. A source of the select transistor ST1 is connected to one end of the memory transistors MT connected in series. The other end of the memory transistors MT connected in series is connected to a drain of the select transistor ST2.

In the same block BLK, a source of the select transistor ST2 is connected to a source line SL. A gate of the select transistor ST1 of each string unit SU is connected to a corresponding select gate line SGD. A gate of the memory transistor MT is connected to the corresponding word line WL. A gate of the select transistor ST2 is connected to a corresponding select gate line SGS.

The plurality of NAND strings NS to which the same column address CA is allocated are connected to the same bit line BL between the plurality of blocks BLK. The source line SL is connected between the plurality of blocks BLK.

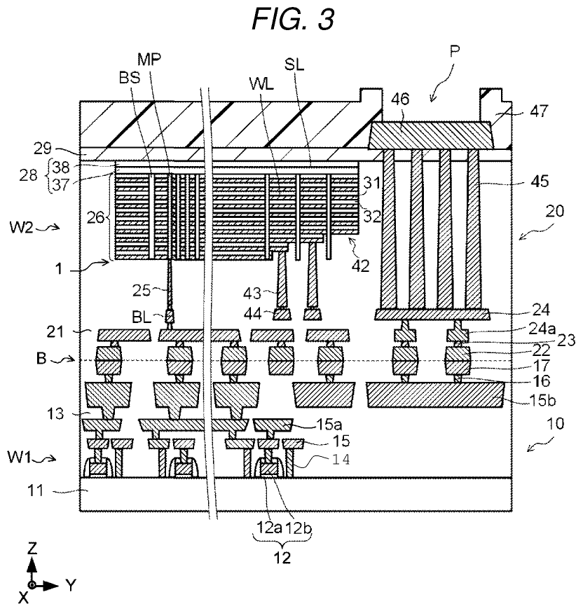

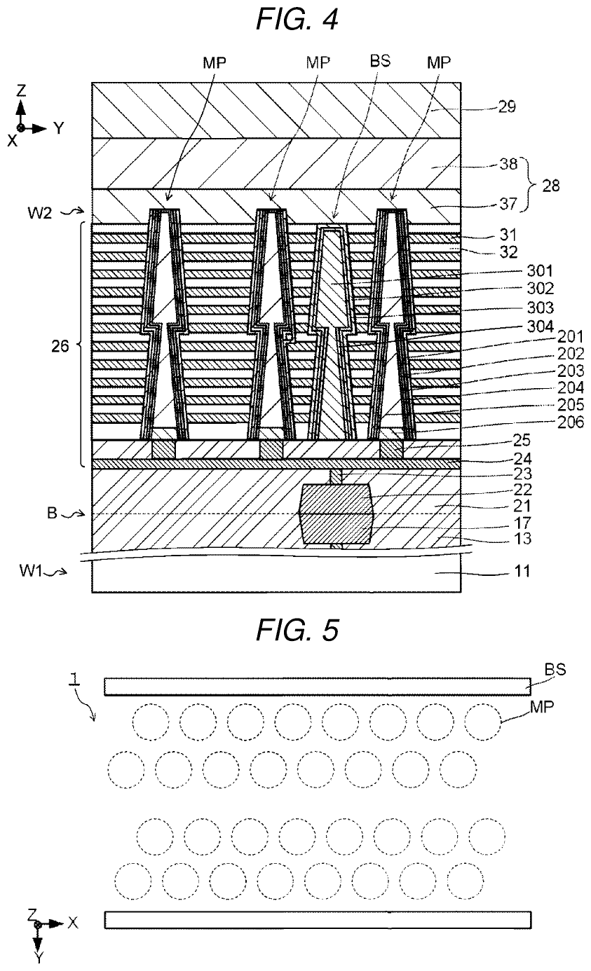

FIG. 3 is a schematic cross-sectional view illustrating an example structure of the semiconductor memory device according to the embodiment. FIG. 4 is an enlarged schematic view illustrating a part of a cross-section of the semiconductor memory device according to the embodiment. FIGS. 3 and 4 illustrate an X axis direction substantially parallel to a surface of a semiconductor substrate 11, a Y axis direction substantially perpendicular to the X axis along the surface, and a Z axis direction intersecting the surface substantially perpendicularly. “Substantially parallel” may include not only a parallel direction but also directions deviating by ±10 degrees from a parallel direction. “Substantially perpendicular” may include not only a perpendicular direction but also directions deviating by ±10 degrees from a perpendicular direction. The Z axis direction is, for example, a thickness direction of the semiconductor substrate 11.

The semiconductor memory device includes a circuit region 10 and an array region 20. The circuit region 10 includes peripheral circuits such as the command register 2, the address register 3, the sequencer 4, the driver 5, the row decoder 6, and the sense amplifier 7. The peripheral circuit may be configured as, for example, a CMOS circuit. The array region 20 includes the memory cell array 1.

The semiconductor memory device is formed by, for example, bonding a circuit wafer W1 including the circuit region 10 to an array wafer W2 including the array region 20. FIG. 3 illustrates a bonded surface B of the circuit region 10 and the array region 20.

The circuit region 10 includes the semiconductor substrate 11, a transistor 12, an interlayer insulating film 13, a contact plug 14, a wiring layer 15 including a plurality of wirings (such as wiring layer 15a and wiring layer 15b), a via plug 16, and a metal pad 17.

The array region 20 includes an interlayer insulating film 21, a metal pad 22, a via plug 23, a wiring layer 24 including a plurality of wirings, a contact plug 25, a stacked body 26, a memory pillar MP, a structure body BS, a source layer 28, and an insulating film 29. FIG. 3 illustrates one contact plug 25 among a plurality of contact plugs 25.

The semiconductor substrate 11 is, for example, a semiconductor substrate such as a silicon (Si) substrate. The transistor 12 is provided on the semiconductor substrate 11, and includes a gate insulating film 12a and a gate electrode 12b. The transistor 12 is part of, for example, the above-described CMOS circuit. The interlayer insulating film 13 is provided on the semiconductor substrate 11 and covers the transistor 12. The interlayer insulating film 13 is, for example, a silicon oxide film (SiO₂ film) or a stacked film including a SiO₂ film and another insulating film.

The contact plug 14, the wiring layer 15, the via plug 16, and the metal pad 17 are formed in the interlayer insulating film 13. Specifically, the contact plug 14 is disposed on the semiconductor substrate 11 or on the gate electrode 12b of the transistor 12. In FIG. 3, the contact plug 14 on the semiconductor substrate 11 is provided on a source region and a drain region (neither of which are illustrated) of the transistor 12. The wiring layer 15 is disposed on the contact plug 14. The via plug 16 is disposed on the wiring layer 15. The metal pad 17 is disposed on the via plug 16 above the semiconductor substrate 11. The metal pad 17 is, for example, a copper (Cu) layer.

The interlayer insulating film 21 is formed on the interlayer insulating film 13. The interlayer insulating film 21 is, for example, a SiO₂ film or a stacked film including a SiO₂ film and another insulating film.

The metal pad 22, the via plug 23, the wiring layer 24, and the contact plug 25 are formed in the interlayer insulating film 21. Specifically, the metal pad 22 is disposed on the metal pad 17 above the semiconductor substrate 11. The metal pad 22 is, for example, a Cu layer. The via plug 23 is disposed on the metal pad 22. The wiring layer 24 is disposed on the via plug 23. In FIG. 3, one of the plurality of wirings in the wiring layer 24 is illustrated, and the wiring functions as the bit line BL. The contact plug 25 is disposed on the wiring layer 24.

The stacked body 26 is provided on the interlayer insulating film 21, and includes a plurality of conductive layers 31 and a plurality of insulating layers 32 alternately stacked in a direction substantially parallel to the Z axis direction. The conductive layer 31 is, for example, a metal layer including a tungsten (W) layer, and functions as the word line WL. The insulating layer 32 is, for example, a SiO₂ film. In the embodiment, thicknesses of the plurality of conductive layers 31 are the same and thicknesses of the plurality of insulating layers 32 are also the same. Here, the thickness of the uppermost insulating layer 32 among the insulating layers 32 may be thicker than the thickness of the other insulating layers 32.

The source layer 28 includes a semiconductor layer 37 and a metal layer 38 formed in order on the stacked body 26, the memory pillar MP, and the structure body BS, and functions as the source line SL. The metal layer 38 is directly formed on the semiconductor layer 37. The semiconductor layer 37 is, for example, a polycrystalline layer such as a polysilicon layer. The metal layer 38 includes, for example, a W layer, a Cu layer, or an aluminum (Al) layer. The semiconductor layer 37 may include P (phosphorus) atoms and H (hydrogen) atoms as impurity atoms.

The insulating film 29 is formed on the source layer 28. The insulating film 29 is, for example, a SiO₂ film.

The circuit region 10 further includes a wiring layer 15a including a plurality of wirings and a wiring layer 15b including a plurality of wirings as illustrated in FIG. 3. In FIG. 3, the wiring layer 15a is provided on the wiring layer 15, the wiring layer 15b is provided on the wiring layer 15a, and the via plug 16 is provided on the wiring layer 15b. The circuit region 10 includes three wiring layers 15, 15a, and 15b in FIG. 3, but the number of wiring layers in the circuit region 10 may be any number other than 3.

The array region 20 further includes a wiring layer 24a including a plurality of wirings as illustrated in FIG. 3. In FIG. 3, the wiring layer 24a is provided on the via plug 23 and the wiring layer 24 is provided on the wiring layer 24a. The array region 20 includes two wiring layers 24 and 24a in FIG. 3, but the number of wiring layers in the array region 20 may be any number other than 2.

The array region 20 further includes the memory cell array 1 provided below the insulating film 29 in the interlayer insulating film 21. The memory cell array 1 includes the stacked body 26, the memory pillar MP, the structure body BS, and the source layer 28. Each conductive layer 31 in the stacked body 26 functions as the word line WL and the source layer 28 functions as the source line SL.

The memory cell array 1 includes a step structure portion 42. Each word line WL is electrically connected to a word wiring layer 44 with a contact plug 43 interposed therebetween. Meanwhile, each memory pillar MP is electrically connected to the bit line BL with the contact plug 25 interposed therebetween, and is electrically connected to the source line SL. The word wiring layer 44 and the bit line BL according to the embodiment are provided in the wiring layer 24.

The array region 20 further includes a plurality of via plugs 45 provided on the wiring layer 24, a metal pad 46 provided on the via plugs 45 and the insulating film 29, and a passivation film 47 provided on the metal pad 46 and the insulating film 29.

The metal pad 46 is, for example, a Cu layer or an Al layer and functions as an external connection pad (bonding pad) of the semiconductor memory device according to the embodiment. The passivation film 47 is, for example, an insulating layer such as a SiO₂ film, and includes an opening P that exposes an upper surface of the metal pad 46. The metal pad 46 can be electrically connected to a mounting substrate or another device by a bonding wire, a soldering ball, a metal bump, or the like via the opening P.

The memory pillar MP extends in a direction substantially parallel to the Z axis in the stacked body 26. The stacked body 26 and the plurality of memory pillars MP form the memory cell array 1.

The plurality of memory pillars MP are segmented into a plurality of groups by the structure body BS. The structure body BS may be, for example, a contact embedded in the stacked body 26. The structure body BS may penetrate the stacked body 26 in a direction substantially parallel to the Z axis and may be connected to the source layer 28.

FIG. 5 is a schematic plan view illustrating a planar layout example of the memory pillar MP and the structure body BS. In FIG. 5, a plurality of memory pillars MP and a plurality of structure bodies BS are illustrated. The plurality of structure bodies BS are disposed along, for example, a direction substantially parallel to the Y axis of the semiconductor substrate 11 and extend in a direction substantially parallel to the X axis. The plurality of memory pillars MP are disposed between the plurality of structure bodies BS. The number of memory pillars MP is not limited to the number illustrated in FIG. 5.

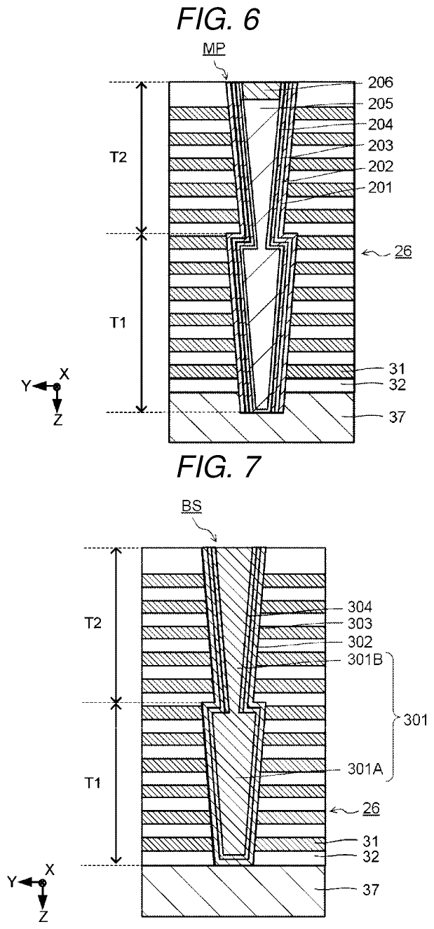

FIG. 6 is a schematic cross-sectional view illustrating an example structure of the memory pillar MP. In FIG. 6, for convenience, the memory pillar MP is illustrated to be upside down compared to the memory pillar MP illustrated in FIGS. 3 and 4. The memory pillar MP may be segmented into a plurality of tiers including a first tier T1 and a second tier T2 provided on the first tier T1. In each of the first tier T1 and the second tier T2, the memory pillar MP extends toward the semiconductor layer 37 so that a width thereof is narrowed in the Y axis direction. The number of plurality of tiers may be any number other than 2.

The memory pillar MP includes a block insulating film 201, a charge storage film 202, a tunnel insulating film 203, a semiconductor layer 204, a core insulating layer 205, and a cap layer 206. The block insulating film 201, the charge storage film 202, the tunnel insulating film 203, the semiconductor layer 204, and the core insulating layer 205 extend in a direction substantially parallel to the Z axis. One memory pillar corresponds to one NAND string NS. The memory pillar MP includes a memory layer. The memory layer includes the block insulating film 201, the charge storage film 202, and the tunnel insulating film 203. The memory layer penetrates the stacked body 26 in a direction substantially parallel to the Z axis. A part of the memory layer may extend in a direction substantially parallel to the Z axis in the semiconductor layer 37.

The block insulating film 201 and the core insulating layer 205 contain, for example, oxygen and silicon. The charge storage film 202 contains, for example, nitrogen and silicon. The tunnel insulating film 203 contains, for example, oxygen and silicon. The block insulating film 201 and the tunnel insulating film 203 may further contain, for example, nitrogen.

More specifically, a hole penetrating the plurality of conductive layers 31 is formed corresponding to the memory pillar MP. The block insulating film 201, the charge storage film 202, and the tunnel insulating film 203 are sequentially stacked on a side surface of the hole. Then, the semiconductor layer 204 is formed so that the side surface comes into contact with the tunnel insulating film 203.

In each of the first tier T1 and the second tier T2, the semiconductor layer 204 extends in a direction substantially parallel to the Z axis in the stacked body 26. The semiconductor layer 204 includes channel formation regions of the select transistor ST1, the select transistor ST2, and the memory transistor MT. Accordingly, the semiconductor layer 204 functions as a signal line that connects current paths of the select transistor ST1, the select transistor ST2, and the memory transistor MT.

In each of the first tier T1 and the second tier T2, the semiconductor layer 204 comes into contact with a surface of the tunnel insulating film 203. The semiconductor layer 204 includes, for example, a polycrystalline layer such as a polysilicon layer. The semiconductor layer 204 may be formed by, for example, crystallizing an amorphous silicon film. The semiconductor layer 204 further extends in the semiconductor layer 37 and comes into contact with the semiconductor layer 37. That is, the semiconductor layer 204 is exposed from the tunnel insulating film 203, the semiconductor layer 37 comes into direct contact with the semiconductor layer 204, and the source layer 28 is electrically connected to the channel formation region of each memory pillar MP. A part of the semiconductor layer 204 may extend in a direction substantially parallel to the Z axis in the semiconductor layer 37.

In each of the first tier T1 and the second tier T2, the core insulating layer 205 is provided inside the semiconductor layer 204. The core insulating layer 205 extends in a direction substantially parallel to the Z axis in the stacked body 26. The core insulating layer 205 is surrounded by the semiconductor layer 204 on an X-Y plane.

The cap layer 206 is provided on the core insulating layer 205 and comes into contact with the semiconductor layer 204. The cap layer 206 contains, for example, oxygen and silicon, or polysilicon that contains N-type impurity elements. For example, when the cap layer 206 contains oxygen and silicon, diffusion of impurity elements can be prevented. When the cap layer 206 is an insulating layer, N-type impurity elements such as phosphorus or arsenic may be injected on a surface of the cap layer 206. The cap layer 206 is connected to the contact plug 25.

FIG. 7 is a schematic cross-sectional view illustrating an example structure of the structure body BS. In FIG. 7, for convenience, the structure body BS is illustrated to be upside down compared to the structure body BS illustrated in FIGS. 3 and 4. The structure body BS may be segmented into a plurality of tiers including the first tier T1 and the second tier T2 provided on the first tier T1. In each of the first tier T1 and the second tier T2, the structure body BS extends toward the semiconductor layer 37 so that a width thereof is narrowed in the Y axis direction. The number of the plurality of tiers may be any number other than 2.

The structure body BS includes a crystalline conductor 301, an insulating film 302, a crystalline semiconductor film 303, and an insulating film 304.

In each of the first tier T1 and the second tier T2, the crystalline conductor 301 extends to be tapered in a direction substantially parallel to the Z axis in the stacked body 26 so that a width thereof is narrowed in the direction substantially parallel to the Y axis toward the semiconductor layer 37. The crystalline conductor 301 contains germanium. The crystalline conductor 301 may contain at least one metal element of tungsten and molybdenum. Preferably, the crystalline conductor 301 does not contain silicon. When the crystalline conductor 301 does not contain silicon, as will be described below, gas that does not contain fluorine atoms can be used as a material for forming the crystalline conductor 301. Examples of the crystalline conductor 301 include a conductor layer formed of germanium as a main component. Here, the main component is a component that has the highest concentration among elements. The present disclosure is not limited thereto, and the crystalline conductor 301 may be a stacked layer of a conductive layer formed of germanium as a main component and a conductive layer formed of a metal element as a main component.

The insulating film 302 is provided between the stacked body 26 and the crystalline conductor 301. The insulating film 302 prevents the plurality of conductive layers 31 from being electrically connected to the crystalline conductor 301. The insulating film 302 contains, for example, silicon and oxygen. Examples of the insulating film 302 include a silicon oxide film.

The crystalline semiconductor film 303 is provided between the insulating film 302 and the crystalline conductor 301. The crystalline semiconductor film 303 is provided to overlap an inner bottom surface BT of a slit ST, which is to be described below, in the Z axis direction. The crystalline semiconductor film 303 contains silicon. Examples of the crystalline semiconductor film 303 include a polysilicon film.

The insulating film 304 is provided between the crystalline semiconductor film 303 and a side surface of the crystalline conductor 301. The insulating film 304 comes into contact with a side surface of the crystalline semiconductor film 303 in a direction substantially parallel to the Y axis. The insulating film 304 is not provided between the crystalline semiconductor film 303 and the crystalline conductor 301 in the Z axis direction. The insulating film 304 is also not provided in the first tier T1 between the crystalline semiconductor film 303 and the crystalline conductor 301 in a direction substantially parallel to the Y axis except for a tapered portion extending from the second tier T2, for example, in the embodiment. The insulating film 304 contains silicon and oxygen. Examples of the insulating film 304 include a silicon oxide film.

The crystalline conductor 301 includes a crystal region 301A and a crystal region 301B.

The crystal region 301A contains germanium. In the crystal region 301A, germanium is preferably a main component. The crystal region 301A comes into contact with the crystalline semiconductor film 303 in a direction substantially parallel to the Z axis while not coming into contact with the insulating film 304 in a direction substantially parallel to the Y axis direction. The crystal region 301A may come into contact with the crystalline semiconductor film 303 in a direction substantially parallel to the X axis and a direction substantially parallel to the Y axis. The crystal region 301A may also contain, for example, polycrystalline.

The crystal region 301B is provided above the crystal region 301A and comes into contact with the insulating film 304 in a direction substantially parallel to the Y axis direction. The crystal region 301B contains germanium or at least one metal element. The at least one metal element is selected from, for example, tungsten and molybdenum. In the crystal region 301B, germanium or the at least one metal element is preferably a main component. The crystal region 301B may also contain, for example, polycrystalline.

The crystal region 301B may contain at least one element selected from silicon, oxygen, carbon, and nitrogen. A concentration of the at least one element is in a range of 1×10²⁰/cm³ or more and 1×10²²/cm³ or less. Accordingly, it is possible to improve the Young's modulus and flexural strength. The concentration of each element can be measured by, for example, energy-dispersive X-ray spectroscopy (EDX). When the crystal region 301B contains silicon, a silicon concentration in the crystalline conductor 301 is preferably lower than a germanium concentration in the crystal region 301A.

An interface between the crystal regions 301A and 301B may not be observable. Here, the crystal regions 301A and 301B can be distinguished from a difference in composition by, for example, elementary analysis. The present disclosure is not limited thereto, and for example, a portion coming into contact with the crystalline semiconductor film 303 in a direction substantially parallel to the Y axis may be set as the crystal region 301A, and a portion coming into contact with the insulating film 304 in a direction substantially parallel to the Y axis may be set as the crystal region 301B.

Next, an example of a method of manufacturing the semiconductor memory device illustrated in FIG. 3 will be described. Here, in particular, a series of manufacturing processes of forming the structure body BS will be described. A cross-sectional structure of the array wafer W2 during manufacturing is illustrated in FIGS. 8, 9, 10, 11, 12, and 13. FIGS. 8 to 13 are schematic cross-sectional views illustrating an example of a method of manufacturing the semiconductor memory device. Since other portions of the circuit region 10 and the array region 20 such as the semiconductor substrate 11, the stacked body 26, the interlayer insulating film 21, and the memory pillar MP can be formed by a known method, description thereof will be omitted.

As illustrated in FIG. 8, the slit ST is formed. The slit ST extends in a direction substantially parallel to the Z axis in the stacked body 26 including the memory pillar MP and penetrates the stacked body 26. The slit ST segments the plurality of memory pillars MP extending to be tapered along the Z axis in the stacked body 26. The slit ST includes the inner bottom surface BT and an inner wall surface SW. The slit ST can be formed by, for example, partially etching the stacked body 26 in a direction substantially parallel to the Z axis a plurality of times by etching such as reactive ion etching (RIE)

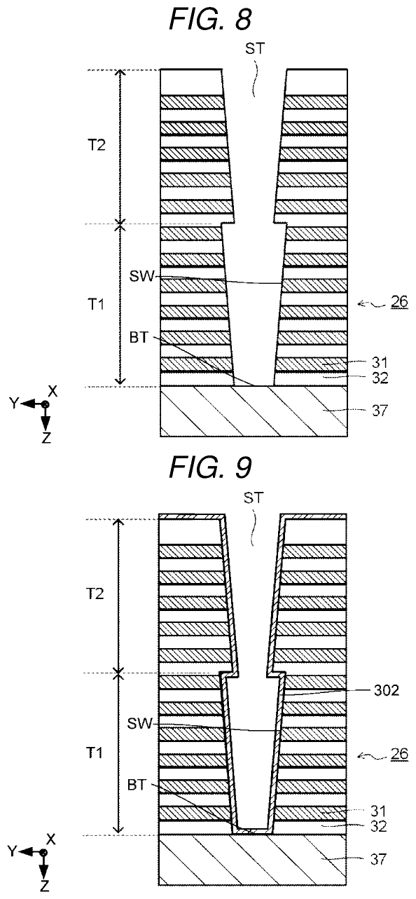

Subsequently, as illustrated in FIG. 9, the insulating film 302 is formed. The insulating film 302 is formed on the inner bottom surface BT and on the inner wall surface SW of the slit ST. The insulating film 302 can be formed by, for example, forming a silicon oxide film by low-pressure chemical vapor deposition (LP-CVD).

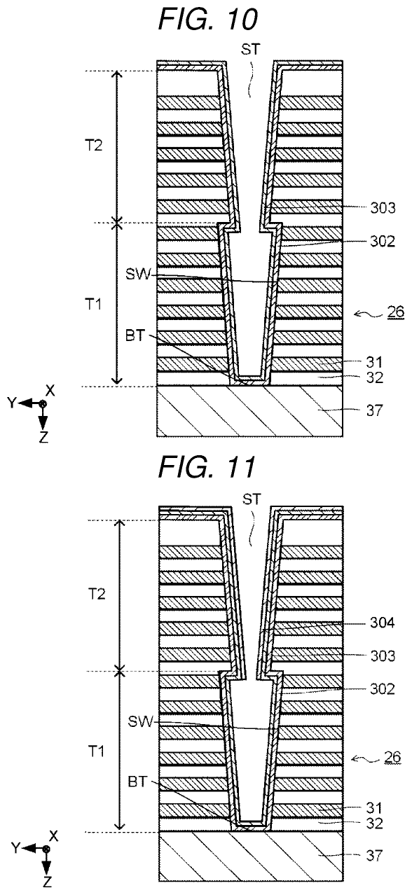

Subsequently, as illustrated in FIG. 10, the crystalline semiconductor film 303 is formed. The crystalline semiconductor film 303 is formed on the inner bottom surface BT and on the inner wall surface SW with the insulating film 302 interposed therebetween. The crystalline semiconductor film 303 can be formed by, for example, forming a silicon film by LP-CVD.

Subsequently, as illustrated in FIG. 11, the insulating film 304 is formed. The insulating film 304 is formed on the crystalline semiconductor film 303 so that at least a part of a first portion of the crystalline semiconductor film 303 overlapping the inner wall surface SW in a direction substantially parallel to the X axis and a direction substantially parallel to the Y axis is covered and a second portion of the crystalline semiconductor film 303 overlapping the inner bottom surface BT in a direction substantially parallel to the Z axis is exposed. A part of the first portion of the crystalline semiconductor film 303 adjacent to the inner bottom surface BT may be exposed from the insulating film 304. In the embodiment, for example, the crystalline semiconductor film 303 on a side surface and a bottom surface of the first tier T1 is exposed from the insulating film 304. The crystalline semiconductor film 303 on a side surface of the second tier T2 is covered with the insulating film 304. The insulating film 304 is, for example, a silicon oxide film that is formed by ALD. The insulating film 304 covers at least a part of the first portion of the crystalline semiconductor film 303 and exposes the second portion of the crystalline semiconductor film 303 from the insulating film 304 by, for example, adjusting conditions when forming the film such as pressure, temperature, and time.

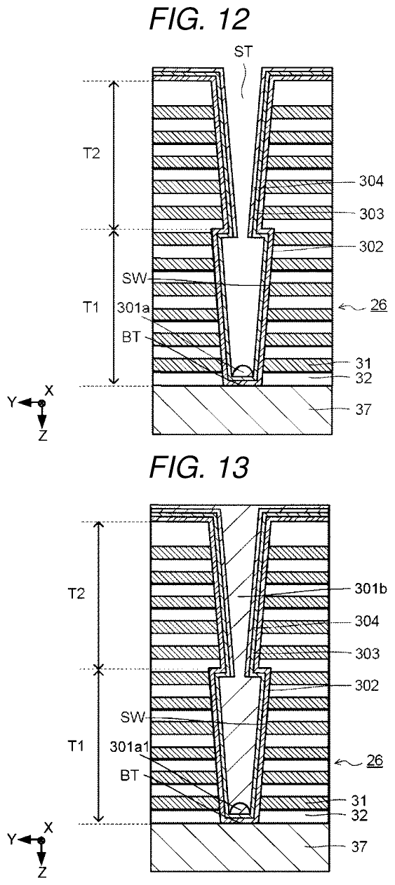

Subsequently, as illustrated in FIG. 12, an amorphous body 301a is formed on the second portion of the crystalline semiconductor film 303. The amorphous body 301a comes into contact with the crystalline semiconductor film 303 in a direction substantially parallel to the Z axis. The amorphous body 301a may come into contact with the crystalline semiconductor film 303 in a direction substantially parallel to the X axis and a direction substantially parallel to the Y axis. The amorphous body 301a contains germanium. The amorphous body 301a is formed by, for example, depositing germanium by CVD. The amorphous body 301a may include, for example, a plurality of grains.

The amorphous body 301a containing germanium is not formed on a surface of the insulating film 304 that is a silicon oxide film, and is formed only on a surface of the crystalline semiconductor film 303. The reason for this is that oxygen atoms on the surface of the silicon oxide film bond with silicon atoms, and thus cannot bond with germanium atoms.

The amorphous body 301 a is preferably formed at a temperature of 300° C. or more and 900° C. or less. Accordingly, it is possible to reduce deterioration in the insulating film or the word line of the memory cell.

The amorphous body 301a may be formed by LP-CVD using materials of GeH₄ and an amino compound. Accordingly, it is possible to form a film at a temperature less than 900° C. , for example.

The amorphous body 301a is preferably formed under an atmosphere including hydrogen. Accordingly, it is possible to improve, for example, embeddability of the amorphous body 301a.

Subsequently, as illustrated in FIG. 13, a crystalline conductor including the crystal regions 301A and 301B illustrated in the drawings is formed by forming an electrical conductor 301b above the amorphous body 301a, crystallizing the amorphous body 301a to become a crystalline body 301a1, and growing (epitaxially growing) the crystalline body 301a1. The amorphous body 301a is crystallized, for example, under the environment where the electrical conductor 301b is formed.

The electrical conductor 301b is a semiconductor or a conductor. The electrical conductor 301b contains germanium or at least one metal element. The electrical conductor 301b may be a metal layer containing, for example, tungsten, tungsten carbide, or molybdenum as a main component. The electrical conductor 301b can be formed by depositing materials by, for example, CVD.

When the electrical conductor 301b contains silicon, the electrical conductor 301b is preferably formed by, for example, LP-CVD using materials of at least one first compound selected from a group including GeH₄ and amino compounds containing Ge, and a second compound selected from a group including Si₂H₆, SiH₄, SiH₂Cl₂, SiHCl₃, Si₂Cl₆, SiCl₄, and amino compounds containing Si. Accordingly, it is possible to form a film with good coverage (step coverage), for example.

When the electrical conductor 301b contains oxygen, the electrical conductor 301b is preferably formed by LP-CVD using materials of at least one first compound selected from a group including GeH₄ and amino compounds containing Ge and at least one third compound selected from a group including O₂, O₃, N₂O, NO, and CO. Accordingly, for example, it is possible to add oxygen without a substrate becoming an oxide film.

When the electrical conductor 301b contains nitrogen, the electrical conductor 301b is preferably formed by LP-CVD using materials of at least one first compound selected from a group including GeH₄ and amino compounds containing Ge and at least one fourth compound selected from a group including NH₃, N₂O, and NO. Accordingly, it is possible to add nitrogen without a substrate becoming a nitride.

Thereafter, etchback is executed in a direction substantially parallel to the Z axis until a surface of the insulating layer 32 is exposed by chemical dry etching as illustrated in FIG. 7. The structure body BS is formed by the above processes.

As described above, according to the method of manufacturing the semiconductor memory device of the embodiment, the crystalline conductor 301 including the crystal regions 301A and 301B illustrated in FIG. 7 is formed by forming the amorphous body 301a above the crystalline semiconductor film 303 containing silicon, forming the electrical conductor 301b above the amorphous body 301a, crystallizing the amorphous body 301a to become the crystalline body 301a1, and growing (epitaxially growing) the crystalline body 301a1. Accordingly, it is possible to reduce deterioration in reliability of the semiconductor memory device.

The structure of the semiconductor memory device according to the embodiment is appropriate, for example, when the structure body BS is formed in the slit ST having a high aspect ratio.

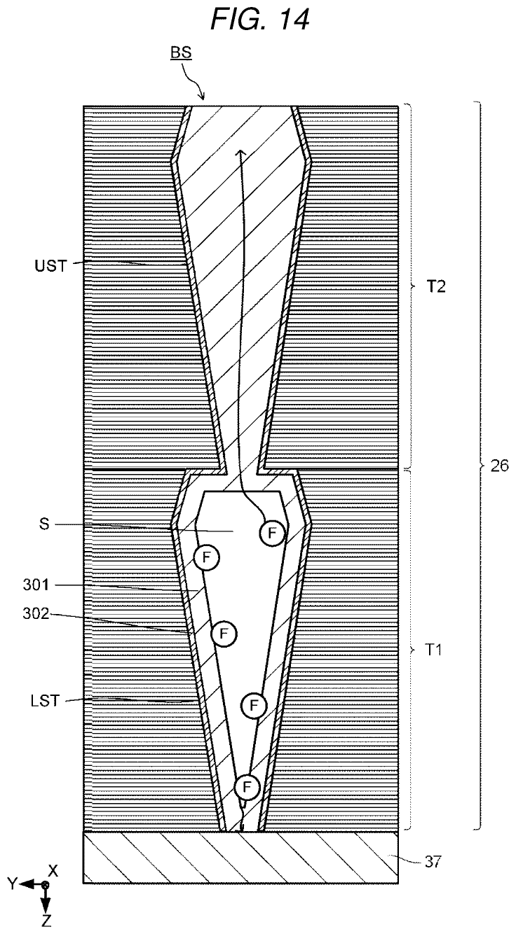

FIG. 14 is a schematic cross-sectional view illustrating an example structure of a structure body BS of the related art. As illustrated in FIG. 14, when the structure body BS is segmented into the first tier T1 and the second tier T2, and a lower slit LST corresponding to the first tier T1 and an upper slit UST corresponding to the second tier T2 are formed, the structure body BS is formed by forming the insulating film 302 on an inner wall surface of both the lower slit LST and the upper slit UST and embedding the crystalline conductor 301 such as silicon on the insulating film 302. The structure body BS has a bow shape in which a width thereof is narrow in a direction substantially parallel to the X axis direction or the Y axis at both ends in the Z axis direction. The structure body BS does not include the crystalline semiconductor film 303 or the insulating film 304. Here, widths of the lower slit LST and the upper slit UST may become narrow in a direction substantially parallel in the Y axis along a depth direction. Therefore, a void S easily occurs inside the crystalline semiconductor region formed in the lower slit LST. The reason for this is that a void easily occurs near a middle portion of the lower slit LST since the crystalline conductor 301 is formed from a side wall surface side of the lower slit LST, or the vicinity of an entrance of the lower slit LST is closed before embedding the vicinity of the middle of the lower slit LST with the crystalline conductor 301 since the width thereof narrows in a direction substantially parallel to the Y axis near an entrance of the lower slit LST or the upper slit UST or a joint portion of the lower slit LST and the upper slit UST. When a continuous length of the void S increases, flexural strength of the crystalline conductor 301 may deteriorate. For example, when the continuous length of the void S is 2 μm or more, flexural strength decreases by 20% or more compared to when the continuous length of the void S is equal to or greater than 0 μm and less than 1 μm. Accordingly, reliability of the semiconductor memory device may deteriorate.

In a semiconductor memory device of the related art, the crystalline conductor 301 is generally formed by depositing silicon by CVD, but fluorine atoms contained in materials easily remain in the void S. Here, the fluorine atoms are diffused toward the upper or lower side of the structure body BS, so that the semiconductor layer 37 below the structure body BS or the interlayer insulating film 21 above the structure body BS is easily damaged. Accordingly, reliability of the semiconductor memory device may deteriorate.

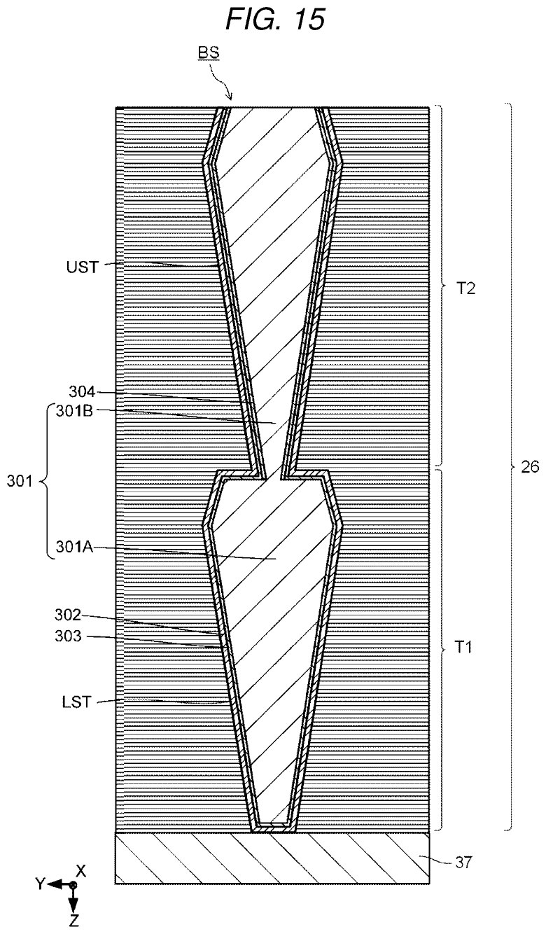

Meanwhile, FIG. 15 is a schematic cross-sectional view illustrating an example structure of the structure body BS in the semiconductor memory device according to the embodiment. As illustrated in FIG. 15, when the lower slit LST and the upper slit UST are formed in the stacked body 26, the crystalline semiconductor film 303 is first formed on a side surface and a bottom surface of the insulating film 302 in the first tier T1 and a side surface of the insulating film 302 in the second tier T2. The insulating film 304 is formed on a side surface of the crystalline semiconductor film 303 in the second tier T2, but not on a side surface of the crystalline semiconductor film 303 in the first tier T1. Accordingly, the amorphous body 301a is not formed on the insulating film 304 and is formed in the first tier T1 in which the crystalline semiconductor film 303 including silicon is exposed. For example, the amorphous body 301a is formed on the inner bottom surface BT of the slit ST. Then, the crystal regions 301A and 301B are formed from the lower slit LST toward the upper slit UST of the slit ST by crystallizing the amorphous body 301a coming into contact with the crystalline semiconductor film 303 to become the crystalline body 301a1 and growing the crystalline body 301a1. Accordingly, since the void S can be reduced in the lower slit LST and the void S can be decreased or removed, embeddability of the crystalline conductor 301 is improved. Accordingly, it is possible to reduce deterioration in flexural strength. Thus, it is possible to reduce deterioration in reliability of the semiconductor memory device.

Material gas containing germanium and not containing fluorine can be selected by growing the crystalline body 301a1 containing germanium as a main component instead of silicon to form the crystalline conductor 301. Therefore, it is possible to prevent damage to the source layer 28 or the interlayer insulating film 21 due to fluorine atoms. Thus, it is possible to reduce deterioration in reliability of the semiconductor memory device.

### First Modification of Structure Body Bs

In the above embodiment, an example in which the crystal regions 301A and 301B contain germanium is described. However, the structure body BS may include another crystal region containing at least one metal element above the crystal regions containing germanium.

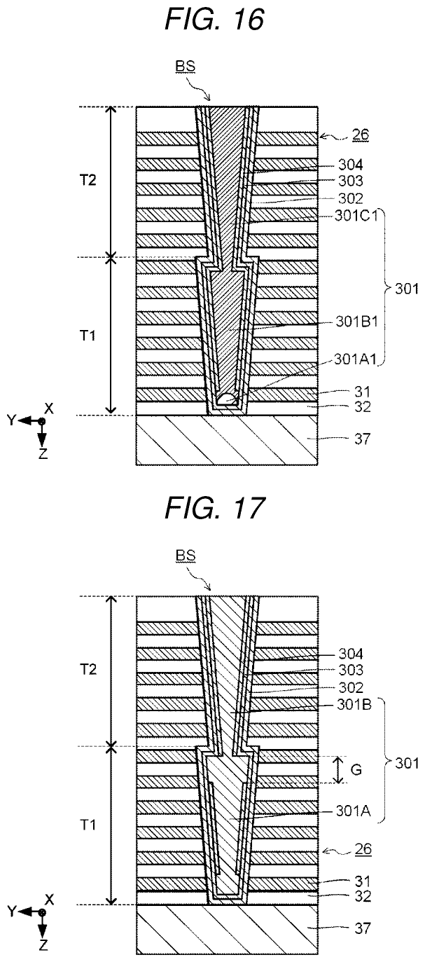

FIG. 16 is a schematic cross-sectional view illustrating a first modification of the structure body BS. As in the structure body BS illustrated in FIG. 7, the structure body BS is segmented into a plurality of tiers including the first tier T1 and the second tier T2 provided above the first tier T1. Hereinafter, portions different from the structure body BS illustrated in FIG. 7 will be described. For the rest of portions, the description of the structure body BS illustrated in FIG. 7 can be appropriately applied.

The structure body BS illustrated in FIG. 16 is different from the structure body BS illustrated in FIG. 7 in that the crystalline conductor 301 includes a crystal region 301A1, a crystal region 301B1, and a crystal region 301C1, and that the insulating film 304 comes into contact with a side surface of the crystalline semiconductor film 303 in the first tier T1 and the second tier T2.

The crystal region 301A1 contains germanium. In the crystal region 301A1, germanium is preferably a main component. The crystal region 301A1 comes into contact with the crystalline semiconductor film 303 in a direction substantially parallel to the Z axis while not coming into contact with the insulating film 304 in a direction substantially parallel to the Y axis direction. The crystal region 301A1 may come into contact with the crystalline semiconductor film 303 in a direction substantially parallel to the X axis and a direction substantially parallel to the Y axis. The crystal region 301A1 may be, for example, polycrystalline. The description of the crystal region 301A can be appropriately applied to other descriptions of the crystal region 301A1.

The crystal region 301B1 is provided above the crystal region 301A1 in the first tier T1 and comes into contact with the insulating film 304 in a direction substantially parallel to the Y axis. The crystal region 301B1 contains at least one metal element. The at least one metal element is selected from, for example, tungsten and molybdenum. In the crystal region 301B1, the at least one metal element is preferably a main component. The crystal region 301B1 may be, for example, polycrystalline.

The crystal region 301C1 is provided above the crystal region 301B1 in the second tier T2 and comes into contact with the insulating film 304 in a direction substantially parallel to the Y axis. The crystal region 301C1 contains at least one metal element. The at least one metal element is selected from, for example, tungsten and molybdenum. In the crystal region 301C1, the at least one metal element is preferably a main component. The crystal region 301C1 may be, for example, polycrystalline. The crystal region 301C1 may contain the same metal element as the crystal region 301B1.

The crystal region 301A1, the crystal region 301B1, and the crystal region 301C1 can be formed by, for example, as in the above described embodiment, forming the amorphous body 301a containing germanium as a main component on the crystalline semiconductor film 303 containing silicon, forming the electrical conductor 301b containing at least one metal element as a main component above the amorphous body 301a, crystallizing the amorphous body 301a to become the crystalline body 301a1, and growing (epitaxially growing) the crystalline body 301a1.

As described above, in the first modification of the structure body BS, the crystal region 301B1 and the crystal region 301C1 containing metal elements are provided on the crystal region 301A1. Thus, for example, electrical resistance of the crystalline conductor 301 can be reduced.

The insulating film 304 comes into contact with the side surface of the crystalline semiconductor film 303 in the first tier T1 and the second tier T2 so that the amorphous body 301a containing germanium as a main component is not formed on the insulating film 304 in a portion of the crystalline semiconductor film 303 overlapping the insulating film 304 in a direction substantially parallel to the Y axis. Therefore, when the amorphous body 301a is crystallized to become the crystalline body 301a1 and is grown (epitaxially grown), crystal growth does not progress to the portion of the crystalline semiconductor film 303 overlapping the insulating film 304 in a direction substantially parallel to the Y axis. Accordingly, it is possible to easily grow the crystalline body 301a1.

### Second Modification of Structure Body Bs

FIG. 17 is an enlarged schematic cross-sectional view illustrating a second modification of the structure body BS. The second modification of the structure body BS is different in that the insulating film 304 is provided with a gap G in a joint of the first tier T1 and the second tier T2. In the gap G, the insulating film 304 is not formed and the crystalline semiconductor film 303 comes into contact with the crystalline conductor 301. Hereinafter, portions different from the structure body BS illustrated in FIG. 7 will be described. For the rest of portions, the description of the structure body BS illustrated in FIG. 7 can be appropriately applied.

The gap G is provided, for example, near the entrance of the first tier T1. For example, in the joint of the first tier T1 and the second tier T2, the width of the slit ST in the second tier T2 in a direction substantially parallel to the Y axis is narrower than the width of the slit ST in the first tier T1 in the direction substantially parallel to the Y axis. It is difficult to form the insulating film 304, and thus the gap G may be formed. However, even when the gap G is formed, in the joint of the first tier T1 and the second tier T2, the width of the slit ST in the second tier T2 in a direction substantially parallel to the Y axis is narrower than the width of the slit ST in the first tier T1 in the direction substantially parallel to the Y axis. Therefore, it is difficult to form the amorphous body 301a in the crystalline semiconductor film 303 coming into contact with a portion of the gap G. Accordingly, in the second modification of the structure body BS, since the insulating film 304 in the second tier T2 comes into contact with a part of the side surface of the crystalline semiconductor film 303, when the amorphous body 301a is crystallized as the crystalline body 301a1 and the crystalline body 301a1 is grown (epitaxially grown), crystal growth does not progress to the portion of the crystalline semiconductor film 303 overlapping the insulating film 304 in a direction substantially parallel to the Y axis. Therefore, the crystalline body 301a1 is easily grown.

### Third Modification of Structure Body BS

In the above described embodiment, an example in which the structure body BS is segmented into a plurality of tiers including the first tier T1 and the second tier T2 is described. However, the structure body BS may not include a plurality of tiers.

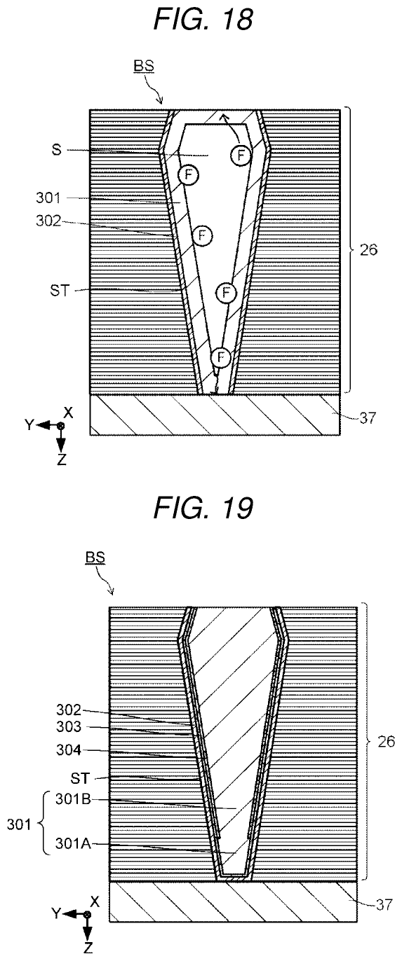

FIG. 18 is a schematic cross-sectional view illustrating an example structure of the structure body BS of the related art. As illustrated in FIG. 18, when the structure body BS does not include a plurality of tiers, the structure body BS is formed by forming the insulating film 302 on the inner wall surface of the slit ST and embedding the crystalline conductor 301 such as silicon on the insulating film 302. The structure body BS does not include the crystalline semiconductor film 303 or the insulating film 304. Here, since the width of the slit ST may be narrowed in a direction substantially parallel to the Y axis along the depth direction, the void S easily occurs in the crystalline semiconductor film 303 formed in the slit ST. The reason for this is that the vicinity of the entrance is blocked before the vicinity of the middle of the slit ST is embedded since the crystalline semiconductor film 303 is formed from the side wall surface side of the slit ST, and the void easily occurs in the vicinity of the middle of the slit ST or the width is narrowed in the vicinity of the entrance of the slit ST.

In the semiconductor memory device of the related art, the crystalline conductor 301 is generally formed by depositing silicon by CVD, but fluorine atoms contained in materials easily remain in the void S. Here, the fluorine atoms are diffused toward the upper or lower side of the structure body BS so that the source layer 28 below the structure body BS or the interlayer insulating film 21 above the structure body BS is easily damaged. Accordingly, reliability of the semiconductor memory device may deteriorate.

Meanwhile, FIG. 19 is a schematic cross-sectional view illustrating a third modification of the structure body BS. As illustrated in FIG. 19, in the slit ST, as in the structure body BS illustrated in FIG. 7, the crystal regions 301A and 301B are formed by forming the crystalline semiconductor film 303 coming into contact with the side surface of the insulating film 302, forming the insulating film 304 coming into contact with the crystalline semiconductor film 303 in a direction substantially parallel to the Y axis, forming the amorphous body 301a coming into contact with the crystalline semiconductor film 303 in the Z axis direction, forming the electrical conductor 301b above the amorphous body 301a, crystallizing the amorphous body 301a to become the crystalline body 301a1, and growing (epitaxially growing) the crystalline body 301a1. Accordingly, the crystalline semiconductor film 303 is formed on the inner bottom surface of the slit ST, the amorphous body 301a coming into contact with the crystalline semiconductor film 303 is crystallized to become the crystalline body 301a1, and the crystalline body 301a1 is grown so that the void S can be reduced and the void S can be decreased or removed. Therefore, embeddability of the crystalline conductor 301 in the slit ST can be improved. Accordingly, it is possible to reduce deterioration in flexural strength. Thus, it is possible to reduce deterioration in reliability of the semiconductor memory device.

Material gas not containing fluorine can be selected by crystallizing the amorphous body 301a containing germanium as a main component instead of silicon to become the crystalline body 301a1 and growing the crystalline body 301a1 to form the crystalline conductor 301. Therefore, damage to the source layer 28 or the interlayer insulating film 21 due to fluorine atoms is prevented. Thus, it is possible to reduce deterioration in reliability of the semiconductor memory device. For the rest of description of the third modification of the structure body BS, the description of the embodiment can be appropriately applied.

The first, second, and third modifications can be combined as appropriate.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of conductive and insulating layers that are alternately stacked in a first direction;
a plurality of memory pillars extending in the first direction in the stacked body; and
a structure body segmenting the plurality of memory pillars and extending in the first direction in the stacked body, wherein the structure body includes
a crystalline conductor extending in the first direction in the stacked body,
a first insulating film provided between the stacked body and the crystalline conductor,
a crystalline semiconductor film provided between the crystalline conductor and the first insulating film and containing silicon, and
a second insulating film provided between the crystalline semiconductor film and a side surface of the crystalline conductor and containing silicon and oxygen, and
the crystalline conductor includes
a first crystal region coming into contact with the crystalline semiconductor film and containing germanium, and
a second crystal region provided on the first crystal region and coming into contact with the second insulating film in a second direction perpendicular to the first direction.

2. The semiconductor memory device according to claim 1, wherein
the structure body is segmented into a plurality of tiers including a first tier and a second tier provided on the first tier,
the crystalline semiconductor film is provided between the crystalline conductor and the first insulating film in the first and second tiers, and
the first crystal region comes into contact with the crystalline semiconductor film in the first tier.

3. The semiconductor memory device according to claim 1, wherein the second insulating film is not provided between the crystalline semiconductor film and the crystalline conductor in the first direction.

4. The semiconductor memory device according to claim 1, wherein the second crystal region contains germanium.

5. The semiconductor memory device according to claim 1, wherein the second crystal region contains at least one metal element selected from a group including tungsten and molybdenum.

6. The semiconductor memory device according to claim 1, wherein
the second crystal region contains at least one element selected from silicon, oxygen, carbon, and nitrogen, and
a concentration of the at least one element in the second crystal region is between 1×10²⁰/cm³ and 1×10²²/cm³.

7. The semiconductor memory device according to claim 1, wherein a silicon concentration in the crystalline conductor is lower than a germanium concentration in the first crystal region.

8. The semiconductor memory device according to claim 1, wherein the first crystal region contains germanium as a main component.

9. The semiconductor memory device according to claim 8, wherein the second crystal region includes a lower part in contact with the first crystal region and an upper part in contact with the lower part, and at an interface of the lower part and the upper part, a width of the lower part in the second direction is larger than a width of the upper part in the second direction.

10. A method of manufacturing a semiconductor memory device, the method comprising:
forming a slit segmenting a plurality of memory pillars extending in a first direction in a stacked body that includes a plurality of conductive and insulating layers that are alternately stacked in the first direction, the slit extending in the first direction in the stacked body and provided with an inner bottom surface and an inner wall surface;
forming a first insulating film on the inner bottom surface and the inner wall surface;
forming a crystalline semiconductor film containing silicon on the first insulating film;
forming a second insulating film containing silicon and oxygen on the crystalline semiconductor film so that at least a part of a first portion of the crystalline semiconductor film overlapping the inner wall surface in a second direction perpendicular to the first direction is covered and a second portion of the crystalline semiconductor film overlapping the inner bottom surface in the first direction is exposed;
forming an amorphous body coming into contact with the crystalline semiconductor film and containing germanium on the inner bottom surface; and
forming a crystalline conductor including a first crystal region containing germanium and a second crystal region provided on the first crystal region and coming into contact with the second insulating film in the second direction by forming an electrical conductor containing germanium or a metal element above the amorphous body in the slit, crystallizing the amorphous body to produce a crystalline body, and growing the crystalline body.

11. The method of manufacturing a semiconductor memory device according to claim 10, wherein the amorphous body is formed at a temperature that is between 300° C. and 900° C.

12. The method of manufacturing a semiconductor memory device according to claim 10, wherein the amorphous body is formed by low-pressure chemical vapor deposition using GeH₄ and an amino compound as materials.

13. The method of manufacturing a semiconductor memory device according to claim 10, wherein the amorphous body is formed under an atmosphere containing hydrogen.

14. The method of manufacturing a semiconductor memory device according to claim 10, wherein the electrical conductor contains germanium.

15. The method of manufacturing a semiconductor memory device according to claim 10, wherein
the electrical conductor contains at least one element selected from silicon, oxygen, carbon, and nitrogen, and
a concentration of the at least one element in the electrical conductor is between 1×10²⁰/cm³ and 1×10²²/cm³.

16. The method of manufacturing a semiconductor memory device according to claim 10, wherein
the electrical conductor contains silicon, and
the electrical conductor is formed by low-pressure chemical vapor deposition using materials of at least one first compound selected from a group including GeH₄ and amino compounds containing Ge and a second compound selected from a group including Si₂H₆, SiH₄, SiH₂Cl₂, SiHCl₃, Si₂Cl₆, SiCl₄, and amino compounds containing Si.

17. The method of manufacturing a semiconductor memory device according to claim 10, wherein
the electrical conductor contains oxygen, and
the electrical conductor is formed by low-pressure chemical vapor deposition using materials of at least one first compound selected from a group including GeH₄ and amino compounds containing Ge and at least one third compound selected from a group including O₂, O₃, N₂O, NO, and CO.

18. The method of manufacturing a semiconductor memory device according to claim 10, wherein
the electrical conductor contains nitrogen, and
the electrical conductor is formed by low-pressure chemical vapor deposition using materials of at least one first compound selected from a group including GeH₄ and amino compounds containing Ge and at least one fourth compound selected from a group including NH₃, N₂O, and NO.

19. The method of manufacturing a semiconductor memory device according to claim 10, wherein the electrical conductor contains tungsten, tungsten carbide, or molybdenum.

20. The method of manufacturing a semiconductor memory device according to claim 10, wherein the first crystal region contains germanium as a main component.
